(19) United States
(12) Patent Application Publication
(10) Pub. No.: US 2009/0209428 A1
(43) Pub. Date: Aug. 20, 2009

(54) PRODUCTION METHOD OF Bi-2223-BASED SUPERCONDUCTING WIRE

(75) Inventor: Masashi Kikuchi, Osaka (JP)

Correspondence Address: DRINKER BIDDLE & REATH (DC), 1500 K STREET, N.W., SUITE 1100, WASHINGTON, DC, 20005-1209, US

(73) Assignee: Sumitomo Electric Industries, Ltd., Osaka-shi, Osaka (JP)

(21) Appl. No.: 12/159,830

(22) PCT Filed: Oct. 9, 2007
(86) PCT No.: PCT/JP2007/069649

§ 371 Date: Jul. 1, 2008

(30) Foreign Application Priority Data
Nov. 6, 2006 (JP) 2006-300083
Sep. 11, 2007 (JP) 2007-235647

(51) Int. Cl. H01L 39/24

(52) U.S. Cl. 505/430; 29/599

(57) ABSTRACT

The invention offers a method of producing a Bi-2223-based superconducting wire. The method has a preparing step for preparing a precursor 11 that is a powder and that is formed of a main phase, composed of a Bi-2212 phase, and the remainder, composed of a Bi-2223 phase and a nonsuperconducting phase, a filling step for filling the precursor into a metallic tube at a pressure of at most 1,000 Pa, and a sealing step for sealing the metallic tube filled, at a pressure of at most 1,000 Pa, with the precursor. The method decreases the intrusion of impurity gases and thereby increases the critical-current value.

### TECHNICAL FIELD

The present invention relates to a production method of a Bi-2223-based superconducting wire.

### BACKGROUND ART

A Bi-222-based superconducting wire is formed as a long, tape-shaped wire using a superconductor formed of a Bi-2223 phase through a powder-in-tube method. According to this method, powders, including a powder formed of a superconducting phase, are filled into a metallic tube to produce a single-filament wire. Subsequently, a plurality of single-filament wires are bundled together to be inserted into a sheath portion. Thus, a multifilament structure is obtained. The base wire having the multifilament structure is subjected to processes such as drawing and rolling to achieve the shape of a tape. The tape-shaped wire undergoes a heat treatment to be sintered. Thus, a Bi-2223-based superconducting wire, which has superconductivity, can be produced.

In the foregoing production method, when the powders are filled into the metallic tube in the atmosphere, impurity gases, such as polar molecules, are adsorbed at 1,000 ppm or more. By the subsequent forming process such as drawing and rolling, the powders are highly densified. Consequently, the adsorbed impurity gases produce voids between crystals of the superconductor or combine with the powders to create disturbances in the superconducting filament. As a result, a problem of decreasing the critical-current value is caused.

In addition, when the powders are filled into the metallic tube in the atmosphere, the air resistance prevents the achieving of a pack density of at least 30%. In the region of a powder having a low pack density, the large number of voids increases the density variations in the forming process such as drawing and rolling. This increase causes orientation disturbances in the Bi-2223-based superconducting crystals. As a result, a problem of decreasing the critical-current value is also caused.

In addition, to remove the adsorbed impurity gases, a heat treatment is sometimes performed. In this case, the pressure difference between the inside and outside of the metallic tube is great at the time of the heating. This great difference decreases the pack density of the powder. The decrease in the pack density of the powder also causes a problem of decreasing the critical-current value.

In view of the above circumstances, to remove the impurity gases in the metallic tube, the published Japanese patent applications Tokukai 2004-87488 (Patent literature 1) and Tokukai 2001-184956 (Patent literature 2) have disclosed methods in which the opening of the metallic tube filled with the powder is sealed under a pressure-reduced condition.
Patent literature 1: the published Japanese patent application Tokukai 2004-87488.
Patent literature 2: the published Japanese patent application Tokukai 2001-184956.

### DISCLOSURE OF THE INVENTION

### Problem to be Solved by the Invention

Nevertheless, even in the methods disclosed by Patent literatures 1 and 2 described above, impurity gases are adsorbed when the powder is filled into the metallic tube. Consequently, there remains a scope for the improvement in the removal of the impurity gases.

In view of the above circumstances, an object of the present invention is to offer a method of producing a Bi-2223-based superconducting wire, in which method, the critical-current value is increased by decreasing the ingress of impurity gases both at the time a precursor is filled into the metallic tube and at the time the metallic tube is sealed.

### Means to Solve the Problem

The method of the present invention for producing a Bi-2223-based superconducting wire is provided with a preparing step, a filling step, and a sealing step. The preparing step performs the preparing of a precursor that is a powder and that is formed of a main phase, composed of a Bi-2212 phase, and the remainder, composed of a Bi-2223 phase and a nonsuperconducting phase. The filling step performs the filling of the precursor into a metallic tube at a pressure of at most 1,000 Pa. The sealing step performs the sealing of the metallic tube filled, at a pressure of at most 1,000 Pa, with the precursor.

According to the method of the present invention for producing a Bi-2223-based superconducting wire, the performing of the filling step and the sealing step at a pressure of at most 1,000 Pa can not only decrease impurity gases at the time the precursor is filled into the metallic tube but also seal the metallic tube in a state where the impurity gases are decreased. Consequently, in the forming process such as drawing and rolling, the generation of the disturbance in the orientation of the Bi-2223 superconducting phase due to the presence of the impurity gases can be prevented. As a result, the critical-current value can be increased.

In the foregoing method of producing a Bi-2223-based superconducting wire, it is desirable that the filling step and the sealing step be performed in an atmosphere containing oxygen.

When oxygen is contained in the metallic tube in the filling step and the sealing step, during the heat treatment subsequent to the sealing step, the reaction from the Bi-2212 phase of the precursor to the Bi-2223 phase can be promoted. Consequently, a Bi-2223-based superconducting wire having a high critical-current value can be produced.

In the foregoing method of producing a Bi-2223-based superconducting wire, it is desirable that the filling step and the sealing step be performed in an atmosphere having an oxygen partial pressure of at least 1 Pa and at most 100 Pa.

When this condition is met, in the heat treatment subsequent to the sealing step, the reaction from the Bi-2212 phase of the precursor to the Bi-2223 phase can be promoted. Consequently, a Bi-2223-based superconducting wire having a high critical-current value can be produced.

In the foregoing method of producing a Bi-2223-based superconducting wire, it is desirable that the filling step and the sealing step be performed in the same chamber. This condition can facilitate the production at the above-described pressure.

In the foregoing method of producing a Bi-2223-based superconducting wire, it is desirable that a heating step be further provided between the filling step and the sealing step and that the heating step perform the heating of the metallic tube filled with the precursor at a temperature of at least 100° C. and at most 800° C. and at a pressure of at most 1,000 Pa.

When this condition is satisfied, the impurity gases adsorbed to the precursor filled in the metallic tube can be further removed. Consequently, a Bi-2223-based superconducting wire having a high critical-current value can be produced.

In the foregoing method of producing a Bi-2223-based superconducting wire, it is desirable that the filling step, the heating step, and the sealing step be performed in the same chamber. This condition can facilitate the production at the above-described pressure.

In the foregoing method of producing a Bi-2223-based superconducting wire, it is desirable that the precursor filled in the metallic tube have a pack density of at least 30% and at most 50% after undergoing the filling step.

When this condition is met, in the produced Bi-2223-based superconducting wire, filaments, which have the Bi-2223 phase as the main phase, can increase their density. As a result, the critical-current value can be increased.

In the foregoing method of producing a Bi-2223-based superconducting wire, it is desirable that the preparing step perform the preparing of the precursor in which the Bi-2212 phase has a superconducting transition temperature of at most 74 K.

When the superconducting transition temperature is at most 74 K, the amount of oxygen contained in the Bi-2223 phase can be significantly increased. Consequently, in the heat treatment subsequent to the sealing step, the reaction from the Bi-2212 phase of the precursor to the Bi-2223 phase can be effectively promoted. As a result, a Bi-2223-based superconducting wire having a high critical-current value can be produced.

In the above description, the term “superconducting transition temperature” means the temperature at which the material comes to be in a superconducting state. The superconducting transition temperature is obtained through the following method. First, a temperature-susceptibility curve is obtained through the measurement using a superconducting quantum interference device (SQUID). Then, by using the curve, the superconducting transition temperature is determined as the temperature at which the magnetization shows 0.5% of the magnitude of the magnetization at 5 K.

In the foregoing method of producing a Bi-2223-based superconducting wire, it is desirable that the preparing step perform the preparing of the precursor having a water content of at most 450 ppm.

When the water as an impurity is at most 450 ppm, the generation of the disturbance in the orientation of the Bi-2223 superconducting phase due to the performing of the forming process can be effectively suppressed. This suppression enables the production of a Bi-2223-based superconducting wire that can have a significantly increased critical-current value.

In the above description, the “water content” is a value measured by the Karl Fischer method. More specifically, the water content is obtained through the following method. The first step performs the measuring of the quantity of water extracted from the specimen heated up to 900° C. Then, the quantity of water is divided by the weight of the specimen to obtain the water content.

### EFFECT OF THE INVENTION

According to the method of the present invention for producing a Bi-2223-based superconducting wire, the critical-current value can be increased because the ingress of impurity gases can be decreased both at the time the precursor is filled into the metallic tube and at the time the metallic tube is sealed.

### BRIEF DESCRIPTION OF THE DRAWING

FIG. 1 is a schematic perspective view showing a Bi-2223-based superconducting wire produced by a method of producing a Bi-2223-based superconducting wire in an embodiment of the present invention.

FIG. 2 is a flow chart showing a method of producing a Bi-2223-based superconducting wire in an embodiment of the present invention.

FIG. 3 is a schematic diagram for explaining a method of producing a Bi-2223-based superconducting wire in an embodiment of the present invention.

### EXPLANATION OF THE SIGN

10: Unit wire
11: Precursor
12: Metallic tube
13: Sealing member
20: Chamber
21: Main compartment
22: Evacuation device
23: Subcompartment
24: Heater
25: Material supplier
26: Material introducer
100: Superconducting wire
110: Sheath portion
111: Filament

### BEST MODE FOR CARRYING OUT THE INVENTION

Embodiments of the present invention are explained below based on the drawing. In the drawing used for the below-described explanation, the same reference sign is given to the same element or an equivalent to avoid duplicated explanations.

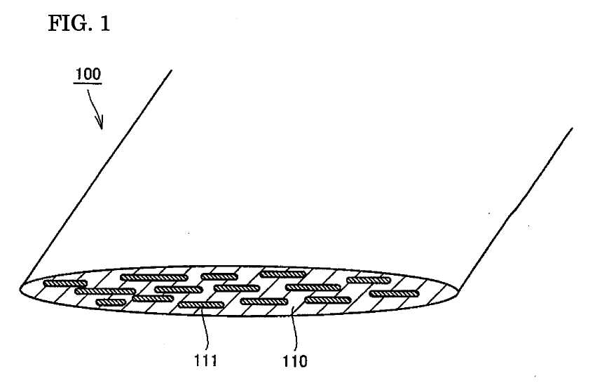

FIG. 1 is a schematic perspective view showing a Bi-2223-based superconducting wire produced by a method of producing a Bi-2223-based superconducting wire in an embodiment of the present invention. In reference to FIG. 1, an explanation is given to the Bi-2223-based superconducting wire in this embodiment of the present invention. As shown in FIG. 1, a Bi-2223-based superconducting wire 100 in this embodiment has filaments 111, which are a plurality of superconductors extending in the direction of the length, and a sheath portion 110 that covers the filaments 111. The material of each of the multiple filaments 111 is formed of a main phase, composed of a Bi-2223 phase in which the atomic ratios of (bismuth and lead):strontium:calcium:copper are expressed approximately as 2:2:2:3, and the remainder, composed of a Bi-2212 phase and unavoidable impurities. The material of the sheath portion 110 is composed of metal such as silver or silver alloy. In the above description, the term “main phase” is used to mean that the Bi-2223 phase constitutes at least 60% of the filament 111.

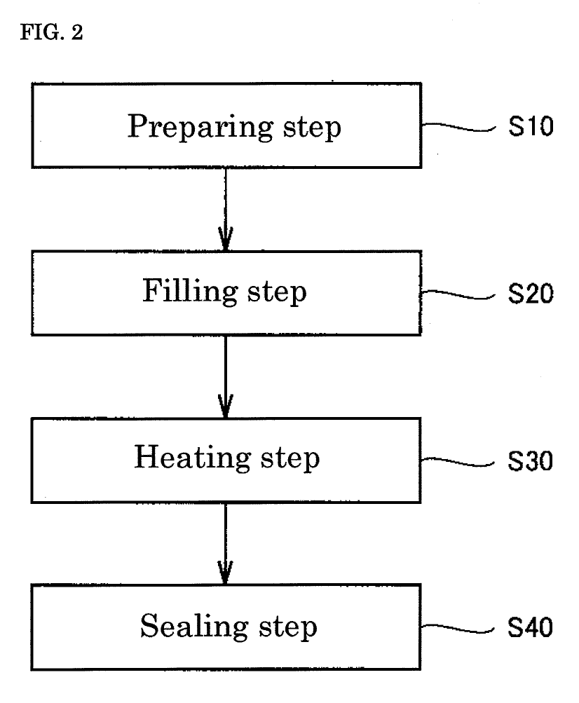

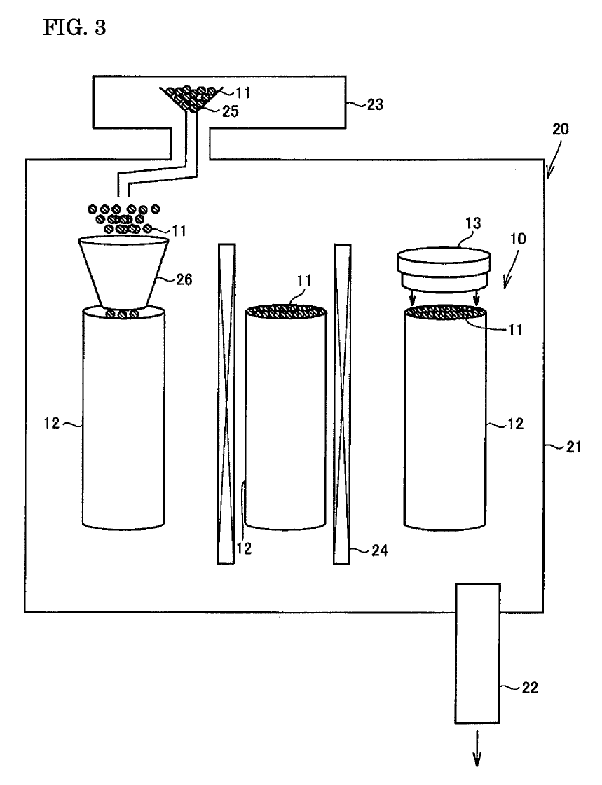

Next, in reference to FIGS. 1 to 3, the method of producing the Bi-2223-based superconducting wire in this embodiment of the present invention is explained below. FIG. 2 is a flow chart showing the method of producing the Bi-2223-based superconducting wire in this embodiment of the present invention. FIG. 3 is a schematic diagram for explaining the method of producing the Bi-2223-based superconducting wire in this embodiment of the present invention.

In the method of producing the Bi-2223-based superconducting wire in this embodiment, a filling step (S20), a heating step (S30), and a sealing step (S40) all shown in FIG. 2 are performed in the same chamber, which is a chamber 20. The chamber 20 has a main compartment 21, an evacuation device 22, and a subcompartment 23. The evacuation device 22 can adjust the inside of the main compartment 21 and the subcompartment 23 to a pressure of 1,000 Pa or below. The main compartment 21 is connected with the subcompartment 23. The main compartment 21 houses a heater 24 for heating a metallic tube 12 that is filled with a precursor 11. The subcompartment 23 houses a material supplier 25 for supplying the precursor 11 to the metallic tube 12.

As shown in FIGS. 2 and 3, first, a preparing step (S10) is performed. This step performs the preparing of the precursor 11 that is a powder and that is formed of a main phase, composed of a Bi-2212 phase ((BiPb)₂Sr₂Ca₁Cu₂O_{Z} or Bi₂Sr₂Ca₁Cu₂O_{Z}), and the remainder, composed of a Bi-2223 phase (a (BiPb)₂Sr₂Ca₂Cu₃O_{Z} phase) and a nonsuperconducting phase. The precursor 11 prepared in the preparing step (S10) is the material of the Bi-2223 superconductor included in the filaments 111 of the Bi-2223-based superconducting wire 100. In the above description, the term “main phase” is used to mean that the Bi-2212 phase constitutes at least 60% of the precursor 11.

In the preparing step (S10), Bi, Pb, Sr, Ca, and Cu are used for material powders. The material powders are mixed to obtain a composition ratio of, for example, Bi:Pb:Sr:Ca:Cu=1.7:0.4:1.9:2.0:3.0. The mixed material powder undergoes a plurality of heat treatments at 700° C. to 860° C. or so. The foregoing process complete the preparation of the precursor 11 that is a powder and that is composed of a large amount of powder formed of a Bi-2212 phase, a small amount of powder formed of a Bi-2223 phase, and a small amount of powder formed of a nonsuperconducting phase.

In the preparing step (S10), it is desirable to heat-treat the precursor 11, as required, for example, at 400° C. or more and 800° C. or less before performing the filling step (S20) to remove the gases and water contained in the precursor 11. For example, it is desirable to employ the spray pyrolysis method. In this method, first, sprayed droplets are introduced into a heating furnace to evaporate the solvent and to cause chemical reactions, so that particles are formed through the formation and growth of the nuclei. Then, the particles sinter to obtain the structure and size as a powder.

In the preparing step (S10), it is desirable that the above-described heat treatment be performed in an atmosphere containing oxygen to prepare a precursor in which the Bi-2212 phase has a superconducting transition temperature (Tc) of at most 74 K. In this case, it is desirable that the superconducting transition temperature (Tc) be at most 74 K, more desirably at least 55 K and at most 69 K. When the transition temperature is at 74 K or below, the Bi-2212 phase contains a large amount of oxygen. Consequently, in the below-described heat treatment subsequent to the sealing step (S40), the reaction from the Bi-2212 phase of the precursor to the Bi-2223 phase can be effectively promoted. When the transition temperature is at 69 K or below, the reaction from the Bi-2212 phase of the precursor to the Bi-2223 phase can be further promoted. The lower limit of the superconducting transition temperature is, for example, at least 55 K in view of the shortening of the time necessary for the production. When the heat treatment is performed at the above-described temperature range in an atmosphere containing, for example, at least 50% oxygen, it is possible to obtain the Bi-2212 phase having a superconducting transition temperature (Tc) in the above-described range.

In the preparing step (S10), it is desirable to prepare a precursor having a water content of at most 450 ppm. It is desirable that the water content be at most 450 ppm, more desirably at least 40 ppm and at most 400 ppm. When the water content is at most 450 ppm, the water as an impurity can be decreased. Consequently, in the below-described forming process such as drawing and rolling, the generation of the disturbance in the orientation of the Bi-2223 superconducting phase can be effectively suppressed. This suppression enables the production of a Bi-2223-based superconducting wire that has a significantly increased critical-current value. When the water content is at most 400 ppm, the water as an impurity can be further decreased. Consequently, in the below-described forming process such as drawing and rolling, the generation of the disturbance in the orientation of the Bi-2223 superconducting phase can be more effectively suppressed. The lower limit of the water content is, for example, at least 40 ppm in view of the shortening of the time necessary for the production. For example, by performing the heating at 800° C. using a drying furnace, it is possible to obtain the precursor 11 having a water content in the above-described range.

In the preparing step (S10), it is desirable to prepare the precursor 11 containing a Bi-2212 phase in an over-doped state. The term “over-doped state” is used to mean a state in which oxygen is excessively included in comparison with a state in which oxygen is optimally included to enable the Bi-2212 phase to have the maximum superconducting transition temperature. When the Bi-2212 phase contained in the prepared precursor 11 is in an over-doped state, the reaction from the Bi-2212 phase of the precursor to the Bi-2223 phase can be effectively promoted.

It is desirable that the precursor 11 prepared in the preparing step (S10) have a maximum particle size of at most 10 μm. In addition, it is more desirable that the precursor 11 have an average particle size of at most 2 μm. When these conditions are satisfied, in the below-described filling step (S20), the precursor 11 can be filled into the metallic tube 12 at a further increased density.

It is desirable that the precursor 11 prepared in the preparing step (S10) be placed in the material supplier 25 provided in the subcompartment 23.

Next, as shown in FIG. 2, the filling step (S20) is performed in which the precursor 11 is filled into the metallic tube 12 at a pressure of at most 1,000 Pa. In the filling step (S20), as shown in FIG. 3, the precursor 11 is filled into the metallic tube 12, for example, through the material supplier 25 to use the precursor 11's own weight. In this case, in the main compartment 21, a material introducer 26 may be provided to introduce the precursor 11 into the metallic tube 12.

The material of the metallic tube 12 is not particularly limited. Nevertheless, it is desirable that the material be either a metal selected from the group consisting of Ag (silver), Cu (copper), Fe (iron), Cr (chromium), Ti (titanium), Mo (molybdenum), W (tungsten), Pt (platinum), Pd (palladium), Rh (rhodium), Ir (iridium), Ru (ruthenium), and Os (osmium) or an alloy based on these metals. In view of good processability, low reactivity with the Bi-2223 phase, and capability to speedily remove the heat due to a quenching phenomenon, it is desirable that the metallic tube 12 be made of metal such as silver or silver alloy, which have high thermal conductivity.

In the filling step (S20), the precursor 11 is filled into the metallic tube 12 at a pressure of at most 1,000 Pa. In this case, it is desirable that the pressure be at least 0.001 Pa and at most 900 Pa, more desirably at least 1 Pa and at most 300 Pa. When the precursor 11 is filled into the metallic tube 12 at a pressure exceeding 1,000 Pa, the precursor 11 tends to adsorb impurity gases such as water vapor, carbon, and hydrocarbons. When the pressure is at most 900 Pa, the adsorption of impurity gases to the precursor 11 can be further prevented. When the pressure is at most 300 Pa, the adsorption of impurity gases to the precursor 11 can be yet further prevented. On the other hand, in view of the performance of the equipment, it is desirable that the pressure be at least 0.001 Pa. When the pressure is at least 1 Pa, the pressure in the chamber 20 can be more easily adjusted.

It is desirable that the filling step (S20) be performed in an atmosphere containing oxygen. More specifically, the filling is performed at an oxygen partial pressure of at least 1 Pa and at most 100 Pa. In this case, it is desirable that the oxygen partial pressure be at least 8 Pa and at most 100 Pa. When an oxygen partial pressure is at least 1 Pa, the inside space of the metallic tube 12 contains oxygen. Consequently, the performing of the below-described heat treatment can promote the reaction from the Bi-2212 phase of the precursor 11 to the Bi-2223 phase. When the oxygen partial pressure is at least 8 Pa, the reaction from the Bi-2212 phase of the precursor 11 to the Bi-2223 phase can be further promoted. On the other hand, the oxygen partial pressure of at most 100 Pa prevents the decrease in the pack density of the precursor 11 filled in the metallic tube 12.

It is desirable that after undergoing the filling step (S20), the precursor 11 filled in the metallic tube 12 have a pack density of at least 30% and at most 50%, more desirably at least 33% and at most 40%. The filling of the precursor 11 in an atmosphere having a pressure of at most 1,000 Pa can reduce the air resistance. Consequently, the precursor 11 can be filled into the metallic tube 12 at a pack density in the foregoing range only by using the precursor it's own weight. When the pack density is at least 30%, in the below-described forming process such as drawing and rolling, the filaments 111, which have the Bi-2223 phase as the main phase, can increase their density. As a result, the Bi-2223-based superconducting wire has a further increased critical-current value. When the pack density is at least 33%, the filaments 111 can further increase their density. On the other hand, when the pack density is at most 50%, the inside of the metallic tube 12 can have good air-permeability. Consequently, in the below-described heating step (S30), the inside of the metallic tube 12 can be heated uniformly. This uniformity enables the uniform removal of the impurity gases at the inside. When the pack density is at most 40%, the heating step (S30) can remove the impurity gases more uniformly.

In the above description, the term “pack density” is used to mean the value (%) expressed in the formula {(the weight of the filled precursor 11÷the volume of the space in which the precursor 11 is filled)÷the theoretical density}×100. The theoretical density is a density in a state in which the precursor 11 is packed without gaps as in a single crystal.

When the filling step (S20) performs the filling of the precursor 11 into the metallic tube 12 at a pressure of at most 1,000 Pa, the concentration of the impurity in the metallic tube 12 filled with the precursor 11 becomes at most 1,000 ppm.

Next, as shown in FIG. 2, the heating step (S30) is performed in which the metallic tube 12 filled with the precursor 11 is heated at a temperature of at least 100° C. and at most 800° C. and at a pressure of at most 1,000 Pa. In the heating step (S30), as shown, for example, in FIG. 3, the metallic tube 12 filled with the precursor 11 is heated with the heater 24 placed in the main compartment 21. Because the metallic tube 12 filled with the precursor 11 is placed so as to be enclosed with the heater 24, the metallic tube 12 is moved by using, for example, a robot arm (not shown). Depending on the circumstances, the heating step (S30) may be omitted.

In the heating step (S30), the metallic tube 12 filled with the precursor 11 is heated at a pressure of at most 1,000 Pa. In this case, it is desirable that the pressure be at least 0.001 Pa and at most 900 Pa, more desirably at least 1 Pa and at most 300 Pa. When the pressure is at most 1,000 Pa, it is easy to remove the impurity gases adsorbed to the precursor 11. When the pressure is at most 900 Pa, it is easier to remove the impurity gases adsorbed to the precursor 11. When the pressure is at most 300 Pa, the impurity gases adsorbed to the precursor 11 can be yet further removed. On the other hand, in view of the performance of the equipment, it is desirable that the pressure be at least 0.001 Pa. When the pressure is at least 1 Pa, the pressure in the chamber 20 can be more easily adjusted.

In the heating step (S30), the metallic tube 12 filled with the precursor 11 is heated at a temperature of at least 100° C. and at most 800° C. In this case, it is desirable that the heating temperature be at least 500° C. and at most 800° C. When the temperature is at least 100° C., it is easy to remove the impurity gases adsorbed to the precursor 11 filled in the metallic tube 12 in the filling step (S20). When the temperature is at least 500° C., it is easier to remove the impurity gases adsorbed to the precursor 11. When the temperature is at most 800° C., the precursor 11 is prevented from melting.

As in the filling step (S20), it is desirable that the heating step (S30) be performed in an atmosphere containing oxygen. More specifically, it is desirable that the heating be performed at an oxygen partial pressure of at least 1 Pa and at most 100 Pa.

The pack density of the precursor 11 filled in the metallic tube 12 after the heating step (S30) is the same as that of the precursor 11 filled in the metallic tube 12 after the filling step (S20). In other words, it is desirable that the pack density be at least 30% and at most 50%.

In the heating step (S30), when the metallic tube 12 filled with the precursor 11 is heated at a temperature of at least 100° C. and at most 800° C. and at a pressure of at most 1,000 Pa, the concentration of the impurity in the metallic tube 12 filled with the precursor 11 becomes at most 10 ppm.

Next, the sealing step (S40) is performed in which the metallic tube 12 filled, at a pressure of at most 1,000 Pa, with the precursor 11 is sealed. In the sealing step (S40), as shown, for example, in FIG. 3, the opening at the end of the metallic tube 12 is sealed with a sealing member 13.

In the sealing step (S40), the metallic tube 12 filled with the precursor 11 is sealed at a pressure of at most 1,000 Pa. In this case, it is desirable that the pressure be at least 0.001 Pa and at most 900 Pa, more desirably at least 1 Pa and at most 300 Pa. When the pressure exceeds 1,000 Pa, impurity gases tend to intrude into the metallic tube 12 at the time of the sealing. When the pressure is at most 900 Pa, impurity gases can be further prevented from intruding into the metallic tube 12. When the pressure is at most 300 Pa, impurity gases can be yet further prevented from intruding into the metallic tube 12. On the other hand, in view of the performance of the equipment, it is desirable that the pressure be at least 0.001 Pa. When the pressure is at least 1 Pa, the pressure in the chamber 20 can be more easily adjusted.

As in the filling step (S20), it is desirable that the sealing step (S40) be performed in an atmosphere containing oxygen. More specifically, it is desirable that the sealing be performed at an oxygen partial pressure of at least 1 Pa and at most 100 Pa.

In the sealing step (S40), it is desirable that the metallic tube 12 filled with the precursor 11 be sealed at a temperature of at least 100° C. and at most 800° C. When the temperature is at least 100° C., the adsorption of impurity gases to the precursor 11 can be further prevented at the time of the sealing. When the temperature is at most 800° C., the precursor 11 is prevented from melting.

The pack density of the precursor 11 filled in the metallic tube 12 after the sealing step (S40) is the same as that of the precursor 11 filled in the metallic tube 12 after the filling step (S20). In other words, it is desirable that the pack density be at least 30% and at most 50%.

In the sealing step (S40), the method of sealing the metallic tube 12 filled with the precursor 11 is not particularly limited. In view of the performing of the process of drawing in a state where the metallic tube 12 is sealed, it is desirable that as the sealing method, a bonding method be employed that not only forms a seal capable of withstanding the drawing process but also is applicable to the vacuum sealing. More specifically, it is desirable to employ a sealing method selected from the induction heating, the electron beam welding, the brazing, and the pressure welding of an evacuation nozzle welded to the metallic tube 12.

The sealing member 13 is not particularly limited. Nevertheless, it is desirable to use a sealing member that is made of the same material as that of the metallic tube 12 and that has a shape enabling the fitting to the opening of the metallic tube 12.

The performing of the above-described steps (S10 to S40) can produce a unit wire 10 that is provided with the precursor 11, the metallic tube 12 filled with the precursor 11, and the sealing member 13 for preventing air and other foreign substances from intruding into the metallic tube 12. Next, an explanation is given to a forming process for producing a Bi-2223-based superconducting wire by using the unit wire 10.

The unit wire 10 is processed by drawing to produce a single-filament wire having the precursor 11 as the core member covered with a metal such as silver. A multitude of single-filament wires described above are bundled together to be inserted into a metallic tube made of metal such as silver (multiple-filament insertion). This operation produces a wire having a multifilament structure that has a large number of core members formed of the precursors 11.

In the above description, an explanation is given to the method of producing a multifilament wire. However, in the case of producing a Bi-2223-based superconducting wire having a single-filament structure composed of one unit wire 10, the process of multiple-filament insertion is omitted.

The wire having the multifilament structure is processed by drawing until the wire has an intended diameter. This drawing operation produces a multifilament wire in which the precursors 11 are embedded in the sheath portion 110 made of, for example, silver. Thus, a long multifilament wire is obtained that has the configuration of the superconducting wire 100 in which the precursors 11 are covered with a metal.

Subsequently, the multifilament wire is rolled to obtain a tape-shaped wire. This rolling operation further increases the density of the precursors 11.

The use of the unit wire 10, which has not only a high pack density but also a decreased concentration of impurity gases, prevents the generation of density variations in the above-described forming process such as drawing and rolling. As a result, the generation of the disturbance in the orientation of the Bi-2223 superconducting crystal is not caused.

The tape-shaped wire is heat-treated, for example, at a temperature of 400° C. to 900° C. and at atmospheric pressure. This heat treatment causes the crystal growth in the Bi-2212 phase in the precursor 11. Thus, the filament 111 is formed that has, as the main phase, the superconducting crystal formed of the Bi-2223 phase. The heat treatment does not transform all of the Bi-2212 phase of the precursor 11 into the Bi-2223 phase. Consequently, the filament 111 sometimes contains a superconducting crystal formed of the Bi-2212 phase in which the atomic ratios of (bismuth and lead):strontium:calcium:copper are expressed approximately as 2:2:1:2. The tape-shaped wire may be subjected to the heat treatment and rolling a plurality of times.

The performing of the above-described production steps can produce the Bi-2223-based superconducting wire 100 shown in FIG. 1. The Bi-2223-based superconducting wire 100 is produced by using the unit wires that can reduce the concentration of the impurity gases having intruded into the metallic tube 12. This feature improves the degree of orientation of the crystals of the Bi-2223-based superconducting wire 100, thereby enabling the increase in the critical-current value.

As explained above, the method of producing the Bi-2223-based superconducting wire 100 in this embodiment of the present invention is provided with the following steps:
(a) the preparing step (S10) for preparing the precursor 11 that is a powder and that is formed of a main phase, composed of the Bi-2212 phase, and the remainder, composed of the Bi-2223 phase and the nonsuperconducting phase,
(b) the filling step (S20) for filling the precursor 11 into the metallic tube 12 at a pressure of at most 1,000 Pa, and
(c) the sealing step (S40) for sealing the metallic tube 12 filled, at a pressure of at most 1,000 Pa, with the precursor 11.
   The performing of the filling step (S20) and the sealing step (S40) at a pressure of at most 1,000 Pa can not only decrease impurity gases intruding into the metallic tube 12 at the time the precursor 11 is filled into the metallic tube 12 but also seal the metallic tube 12 in a state where the impurity gases are decreased. Consequently, in the forming process such as drawing and rolling, the generation of the disturbance in the orientation of the Bi-2223 superconducting phase due to the presence of the impurity gases can be prevented. This feature enables the production of the Bi-2223-based superconducting wire 100 having a high critical-current value.

In the above-described method of producing the Bi-2223-based superconducting wire 100, it is desirable that the filling step (S20) and the sealing step (S40) be performed in an atmosphere containing oxygen. When this condition is met, at the time the filling step (S20) and the sealing step (S40) are performed, the inside space of the metallic tube 12 can contain oxygen. Consequently, in the heat treatment subsequent to the sealing step (S40), the reaction from the Bi-2212 phase of the precursor 11 to the Bi-2223 phase can be promoted.

In the above-described method of producing the Bi-2223-based superconducting wire 100, it is desirable that the filling step (S20) and the sealing step (S40) be performed at an oxygen partial pressure of at least 1 Pa and at most 100 Pa. When this condition is met, in the heat treatment subsequent to the sealing step (S40), the reaction from the Bi-2212 phase of the precursor 11 to the Bi-2223 phase can be promoted.

In the above-described method of producing the Bi-2223-based superconducting wire 100, it is desirable that the filling step (S20) and the sealing step (S40) be performed in the same chamber 20. When this condition is met, the production can be easily performed at the foregoing pressure. In addition, the filling step (S20) and the sealing step (S40) can be performed with a high degree of efficiency.

In the above-described method of producing the Bi-2223-based superconducting wire 100, it is desirable that the heating step (S30) be further provided between the filling step (S20) and the sealing step (S40) and that the heating step (S30) perform the heating of the metallic tube 12 filled with the precursor 11 at a temperature of at least 100° C. and at most 800° C. and at a pressure of at most 1,000 Pa. This additional providing can remove an increased amount of impurity gases adsorbed to the precursor 11 filled in the filling step (S20).

In the above-described method of producing the Bi-2223-based superconducting wire 100, it is desirable that the filling step (S20), the heating step (S30), and the sealing step (S40) be performed in the same chamber 20. When this condition is met, the production can be easily performed at the foregoing pressure. In addition, the filling step (S20), the heating step (S30), and the sealing step (S40) can be performed with a high degree of efficiency.

In the above-described method of producing the Bi-2223-based superconducting wire 100, it is desirable that after undergoing the filling step (S20), the precursor 11 filled in the metallic tube 12 have a pack density of at least 30% and at most 50%. This condition increases the density of the Bi-2223 phase in the filaments 111 of the produced Bi-2223-based superconducting wire. As a result, the critical-current value can be increased.

In the above-described method of producing the Bi-2223-based superconducting wire, it is desirable that the preparing step (S10) performs the preparing of the precursor 11 in which the Bi-2212 phase has a superconducting transition temperature of at most 74 K. When the superconducting transition temperature is at most 74 K, the amount of oxygen contained in the Bi-2212 phase can be increased significantly. Consequently, in the heat treatment after the sealing step (S40), the reaction from the Bi-2212 phase of the precursor 11 to the Bi-2223 phase can be effectively promoted. As a result, the filament 111 containing a further increased amount of Bi-2223 phase can be formed. Thus, a Bi-2223-based superconducting wire having a high critical-current value can be produced.

In the above-described method of producing the Bi-2223-based superconducting wire, it is desirable that the preparing step (S10) performs the preparing of the precursor 11 having a water content of at most 450 ppm. When the contained water as an impurity is at most 450 ppm, the generation of the disturbance in the orientation of the Bi-2223 superconducting phase due to the performing of the forming process can be effectively suppressed. This suppression enables the production of a Bi-2223-based superconducting wire that has a significantly increased critical-current value.

### Implementation Example 1

This implementation example conducted a study on the effect of the performing of the operation at a pressure of at most 1,000 Pa in the filling step and the sealing step. More specifically, in Present invention's examples 1 to 15 and Comparative example 1, Bi-2223-based superconducting wires were produced to measure the orientational deviation angle and critical-current value of the individual Bi-2223-based superconducting wires.

### Present Invention's Examples 1 to 15

The Bi-2223-based superconducting wires of Present invention's examples 1 to 15 were produced according to the method of producing the Bi-2223-based superconducting wire in the embodiment of the present invention.

In Present invention's examples 1 to 15, when the filling step (S20) and the heating step (S30) were performed, the heating step (S30) and the sealing step (S40) were performed in the same chamber shown in FIG. 3. Accordingly, in Table I below, the “total pressure” means the pressure (the total pressure: Pa) when the heating step (S30) and the sealing step (S40) were performed in the case where the filling step (S20) and the heating step (S30) were performed. In Table I, the “oxygen pressure” means the oxygen partial pressure when the heating step (S30) and the sealing step (S40) were performed in the case where the filling step (S20) and the heating step (S30) were performed. The oxygen pressure (Pa) was obtained by the following method. First, the concentration of oxygen in the chamber was measured using a concentration meter. Then, the oxygen pressure was calculated by multiplying the total pressure by the concentration.

More specifically, in the preparing step (S10), precursors were prepared each of which was formed of a Bi-2212 phase, Ca₂PbO₄, Ca₂CuO₃, and (Ca,Sr)₁₄Cu₂₄O₄₁. The superconducting transition temperature (Tc) and the water content of the prepared precursors are shown in Table I below. The superconducting transition temperature (Tc) was obtained through the following method. First, a susceptibility curve was obtained through the measurement using a superconducting quantum interference device (SQUID). Then, by using the curve, the temperature (Tc) was determined as a temperature at which the magnetization showed 0.5% of the magnetization at 5 K. The water content was obtained through the following method. First, measurement was conducted to obtain, by using the Karl Fischer method, the quantity of water extracted from the specimen heated up to 900° C. Then, the quantity of water was divided by the weight of the specimen to obtain the water content.

In the filling step (S20), a metallic tube made of silver was filled, at the pressure shown in Table I, with a precursor formed of a Bi-2212 phase, Ca₂PbO₄, Ca₂CuO₃, and (Ca,Sr)₁₄Cu₂₄O₄₁.

In the case where the heating step (S30) was performed, the metallic tube was heated from outside with a heater at a temperature and a pressure both shown in Table I.

In the sealing step (S40), the metallic tube filled with the precursor was sealed by using a sealing member made of silver through the dielectric heating method at a pressure shown in Table I.

The metallic tube filled with the precursor was processed by drawing to produce a single-filament wire. A multitude of single-filament wires described above were bundled together to be inserted into a metallic tube made of silver to obtain a wire having a multifilament structure. The wire having a multifilament structure Was processed by drawing and rolling to produce a tape-shaped wire. The wire was heat-treated for 50 hours at 840° C. and at an oxygen concentration of 8%.

The performing of the above-described steps produced each of the Bi-2223-based superconducting wires in Present invention's examples 1 to 15.

### Comparative Example 1

The method of producing the Bi-2223-based superconducting wire in Comparative example 1 was basically the same as that in Present invention's examples 1 to 15. Only the difference was that the filling step and the sealing step were performed at a pressure exceeding 1,000 Pa, which was 1,050 Pa.

TABLE I

| | | | | | | | Orientational | |
|---|---|---|---|---|---|---|---|---|
| | Total | Oxygen | Heating | Transition | Water | Pack | deviation | Critical-current |
| | pressure | pressure | temperature | temperature | content | density | angle | value |
| | (Pa) | (Pa) | (° C.) | (K) | (ppm) | (%) | (degree) | (A) |
| Example 1 | 1,000 | 0 | Not heated | 72 | 490 | 30.0 | 9.0 | 142.0 |
| Example 2 | 1,000 | 1 | Not heated | 71 | 470 | 30.0 | 8.2 | 167.0 |
| Example 3 | 1,000 | 100 | Not heated | 68 | 470 | 30.0 | 8.3 | 164.0 |
| Example 4 | 10 | 0 | 100 | 69 | 350 | 33.0 | 8.1 | 185.0 |
| Example 5 | 10 | 0 | 800 | 83 | 330 | 33.0 | 8.0 | 181.0 |
| Example 6 | 10 | 0 | Not heated | 69 | 370 | 30.0 | 7.9 | 178.2 |
| Example 7 | 10 | 0 | Not heated | 70 | 360 | 50.0 | 7.8 | 175.3 |
| Example 8 | 900 | 0 | Not heated | 70 | 440 | 31.0 | 8.0 | 185.0 |
| Example 9 | 300 | 0 | Not heated | 73 | 400 | 32.4 | 7.9 | 185.2 |
| Example 10 | 0.01 | 0 | Not heated | 71 | 200 | 40.0 | 7.6 | 191.0 |
| Example 11 | 10 | 0 | 500 | 72 | 230 | 33.0 | 7.3 | 196.0 |
| Example 12 | 10 | 8 | 500 | 65 | 220 | 33.0 | 7.0 | 201.0 |
| Example 13 | 1 | 0.8 | 500 | 62 | 220 | 34.0 | 7.1 | 199.0 |
| Example 14 | 900 | 0 | 500 | 65 | 400 | 33.0 | 8.7 | 161.0 |
| Example 15 | 900 | 1 | 90 | 70 | 420 | 33.0 | 8.1 | 183.7 |
| Comparative | 1,050 | 0 | Not heated | 65 | 710 | 15.0 | 10.1 | 115.0 |
| example 1 | | | | | | | | |

Note:
The term “Present invention's example” is abbreviated as “Example” in this table.

### Evaluation Method

The Bi-2223-based superconducting wires produced in accordance with the method of producing the Bi-2223-based superconducting wire in Present invention's examples 1 to 15 and Comparative example 1 were subjected to measurements of the pack density, orientational deviation angle, and critical-current value using the below-described methods. The measured results are shown in Table I.

The pack density was obtained through the following method. First, after the filling step, a laser beam was applied to the opening of the metallic tube from above. The laser beam was reflected from a mirror to measure the height at which the precursor was filled in the metallic tube. The volume of the space in which the precursor was filled was calculated using the measured height and the bottom area of the metallic tube. The weight of the precursor filled in the metallic tube was also measured. Based on the measured height, the weight of the precursor, and the fact that the theoretical density of the material of the precursor was 6.3 g/cm³, the pack density was calculated using the formula {(the weight of the filled precursor÷the volume of the space in which the precursor is filled)÷the theoretical density}×100.

The orientational deviation angle of the filament of the produced Bi-2223-based superconducting wires in Present invention's examples 1 to 15 and Comparative example 1 was obtained through the following method. First, X-ray diffraction (XRD) is conducted on the superconducting crystal formed of the Bi-2223 phase to obtain the rocking curve of the (0, 0, 24) peak. The full width at half maximum (FWHM) of the obtained rocking curve is the orientational deviation angle. The FWHM is a value corresponding to the inclining angle of the direction of the a-b plane of the superconducting crystal formed of the Bi-2223 phase to the extending direction of the Bi-2223-based superconducting wire (the extending direction coincides with the direction at which the electric current flows in the Bi-2223-based superconducting wire). Therefore, the FWHM is used as an index for indicating the degree of orientation of a superconducting crystal. A small value in the FWHM shows that the a-b plane of the individual superconducting crystal has a good orientation.

The critical-current value was measured at a temperature of 77 K and in the self-magnetic field on each of the produced Bi-2223-based superconducting wires in Present invention's examples 1 to 15 and Comparative example 1. The critical-current value is defined as a value of the current supplied to generate an electric field of 10⁻⁶ V/cm.

### Evaluation Result

As shown in Table I, whereas the Bi-2223-based superconducting wire in Comparative example 1 had a pack density as low as 15%, the Bi-2223-based superconducting wires in Present invention's examples 1 to 15 were able to have a pack density of at least 30% and at most 50%, because they were produced by filling the precursor into the metallic tube at a pressure of at most 1,000 Pa in the filling step (S20). As a result, the orientational deviation angle of the Bi-2223 crystal of the Bi-2223-based superconducting wires in Present invention's examples 1 to 15 was smaller than that of the Bi-2223-based superconducting wire in Comparative example 1. The critical-current value of the Bi-2223-based superconducting wires in Present invention's examples 1 to 15 was higher than that of the Bi-2223-based superconducting wire in Comparative example 1.

In particular, the Bi-2223-based superconducting wire in Present invention's example 12, which was produced by performing the filling step, heating step, and sealing step at an oxygen partial pressure in the range of at least 1 Pa and at most 100 Pa, was able to significantly improve the orientational deviation angle and the critical-current value.

### Implementation Example 2

This implementation example conducted a study on the effect of the condition that the Bi-2212 phase contained in the precursor prepared in the preparing step has a superconducting transition temperature of at most 74 K. More specifically, in Present invention's examples 16 to 21, Bi-2223-based superconducting wires were produced to measure the critical-current value of the individual Bi-2223-based superconducting wires.

### Present Invention's Examples 16 to 21

Present invention's examples 16 to 21 employed basically the same production method as that employed in Present invention's example 12, except for the preparing step (S10).

More specifically, powders formed of a Bi-2212 phase, Ca₂PbO₄, Ca₂CuO₃, and (Ca,Sr)₁₄Cu₂₄O₄₁ were prepared. The powders were heat-treated at a temperature of 650° C. in an atmosphere containing oxygen at a concentration shown in Table II below. Thus, precursors were prepared. The precursors prepared in the preparing step (S10) of Present invention's examples 16 to 21 had superconducting transition temperatures (Tc) shown in Table II below. The superconducting transition temperature (Tc) was measured using the same method as that used in Implementation example 1. The precursors had a water content of 400 ppm. Subsequently, as in Present invention's example 12, the filling step (S20), the heating step (S30), and the sealing step (S40) were performed.

### Evaluation Method

The obtained Bi-2223-based superconducting wires in Present invention's examples 16 to 21 were subjected to the measurement of the critical-current value as in Implementation example 1. The measured results are shown in Table II below.

TABLE II

| | Oxygen | Transition | |
|---|---|---|---|
| | concentration | temperature | Critical-current |
| | (%) | (K) | value (A) |
| Present invention's | 0.1 | 82 | 151 |
| example 16 | | | |
| Present invention's | 1 | 80 | 145 |
| example 17 | | | |
| Present invention's | 10 | 77 | 160 |
| example 18 | | | |
| Present invention's | 50 | 72 | 198 |
| example 19 | | | |
| Present invention's | 80 | 74 | 203 |
| example 20 | | | |
| Present invention's | 100 | 69 | 201 |
| example 21 | | | |

### Evaluation Result

As shown in Tables I and II, the Bi-2223-based superconducting wires in Present invention's examples 16 to 21 had a critical-current value higher than that of the Bi-2223-based superconducting wire in Comparative example 1. In addition, the Bi-2223-based superconducting wires in Present invention's examples 19 to 21, which were produced by using precursors in which the Bi-2212 phase had a superconducting transition temperature of 74 K or below, had a significantly increased critical-current value in comparison with that of the Bi-2223-based superconducting wires in Present invention's examples 16 to 18, which were produced by using precursors in which the superconducting transition temperature exceeded 74 K.

As described above, Implementation example 2 confirmed that to increase the critical-current value effectively, it is effective to cause the Bi-2212 phase contained in the prepared precursor to have a superconducting transition temperature (Tc) of at most 74 K.

### Implementation Example 3

This implementation example conducted a study on the effect of the condition that the precursor prepared in the preparing step has a water content of at most 450 ppm. More specifically, in Present invention's examples 22 to 29, Bi-2223-based superconducting wires were produced to measure the critical-current value of the individual Bi-2223-based superconducting wires.

### Present Invention's Examples 22 to 29

Present invention's examples 22 to 29 employed basically the same production method as that employed in Present invention's example 12, except for the preparing step (S10).

More specifically, powders formed of a Bi-2212 phase, Ca₂PbO₄, Ca₂CuO₃, and (Ca,Sr)₁₄Cu₂₄O₄₁ were prepared by heating them for 8 hours at a temperature of 780° C. In Present invention's examples 22, 23, and 29, the precursors were prepared by exposing the powders to the atmosphere for the time period shown in Table II below to absorb water from the atmosphere. In Present invention's examples 24 to 28, the precursors were prepared by using the powders immediately after the taking-out of them from the drying furnace. The precursors of Present invention's examples 22 to 29 prepared in the preparing step (S10) had the water contents shown in Table III below. The water content was measured using the same method as that used in Implementation example 1. The Bi-2212 phase contained in the precursors had a superconducting transition temperature (Tc) of 61 K. Subsequently, as in Present invention's example 12, the filling step (S20), the heating step (S30), and the sealing step (S40) were performed in Present invention's examples 22 to 29.

### Evaluation Method

The obtained Bi-2223-based superconducting wires in Present invention's examples 22 to 29 were subjected to the measurement of the critical-current value as in Implementation example 1. The measured results are shown in Table III below.

TABLE III

| | Exposure time | Water | |
|---|---|---|---|
| | in the atmosphere | content | Critical-current |
| | (hour) | (ppm) | value (A) |
| Present invention's | 100 | 950 | 155 |
| example 22 | | | |
| Present invention's | 24 | 800 | 165 |
| example 23 | | | |
| Present invention's | 0 | 250 | 198 |
| example 24 | | | |
| Present invention's | 0 | 400 | 203 |
| example 25 | | | |
| Present invention's | 0 | 450 | 192 |
| example 26 | | | |
| Present invention's | 0 | 410 | 199 |
| example 27 | | | |
| Present invention's | 0 | 380 | 201 |
| example 28 | | | |
| Present invention's | 50 | 600 | 157 |
| example 29 | | | |

### Evaluation Result

As shown in Tables I and III, the Bi-2223-based superconducting wires in Present invention's examples 22 to 29 had a critical-current value higher than that of the Bi-2223-based superconducting wire in Comparative example 1. In addition, as shown in Table III, Present invention's examples 24 to 28, which were produced by using precursors having a water content of 450 ppm or less in the preparing step (S10), had a significantly increased critical-current value in comparison with that of Present invention's examples 22, 23, and 29, which were produced by using precursors having a water content of more than 450 ppm.

As described above, Implementation example 3 confirmed that to increase the critical-current value effectively, it is effective to cause the prepared precursor to have a water content of at most 450 ppm.

It is to be considered that the above-disclosed embodiments and examples are illustrative and not restrictive in all respects. The scope of the present invention is shown by the scope of the appended claims, not by the above-described embodiments and examples. Accordingly, the present invention is intended to cover all revisions and modifications included within the meaning and scope equivalent to the scope of the claims.

### INDUSTRIAL APPLICABILITY

The Bi-2223-based superconducting wire produced by the method of the present invention for producing a Bi-2223-based superconducting wire can have an increased critical-current value, because the method can decrease impurity gases both at the time of filling the metallic tube with the precursor and at the time of sealing the metallic tube. Consequently, the Bi-2223-based superconducting wire produced by the method of the present invention for producing a Bi-2223-based superconducting wire can be used, for example, for a superconducting cable, a superconducting transformer, a superconducting fault-current limiter, a superconducting power storage apparatus, and other superconducting apparatuses.

1: A method of producing a Bi-2223-based superconducting wire, the method comprising:
(a) a preparing step for preparing a precursor that is a powder and that is formed of a main phase, composed of a Bi-2212 phase, and the remainder, composed of a Bi-2223 phase and a nonsuperconducting phase;
(b) a filling step for filling the precursor into a metallic tube at a pressure of at most 1,000 Pa; and
(c) a sealing step for sealing the metallic tube filled, at a pressure of at most 1,000 Pa, with the precursor;
in which method, the filling step and the sealing step are performed in an atmosphere containing oxygen having an oxygen partial pressure of at least 1 Pa and at most 100 Pa.

2. (canceled)

3. (canceled)

4: The method of producing a Bi-2223-based superconducting wire as defined by claim 1, wherein the filling step and the sealing step are performed in the same chamber.

5: The method of producing a Bi-2223-based superconducting wire as defined by claim 1, the method further comprising a heating step between the filling step and the sealing step;
the heating step performing the heating of the metallic tube filled with the precursor at a temperature of at least 100° C. and at most 800° C. and at a pressure of at most 1,000 Pa.

6: The method of producing a Bi-2223-based superconducting wire as defined by claim 5, wherein the filling step, the heating step, and the sealing step are performed in the same chamber.

7: The method of producing a Bi-2223-based superconducting wire as defined by claim 1, wherein the precursor filled in the metallic tube has a pack density of at least 30% and at most 50% after undergoing the filling step.

8: The method of producing a Bi-2223-based superconducting wire as defined by claim 1, wherein the preparing step performs the preparing of the precursor in which the Bi-2212 phase has a superconducting transition temperature of at most 74 K.

9: The method of producing a Bi-2223-based superconducting wire as defined by claim 1, wherein the preparing step performs the preparing of the precursor having a water content of at most 450 ppm.
